(19) United States
(12) Patent Application Publication
(10) Pub. No.: US 2026/0188625 A1
(43) Pub. Date: Jul. 2, 2026

(54) SEMICONDUCTOR PROCESSING CHAMBER WITH METAL OR METALLOID FLUORIDE PROCESS EXPOSED COATING

(71) Applicant: Lam Research Corporation, Fremont, CA (US)

(72) Inventors: Robin KOSHY, Fremont, CA (US); Eric A. PAPE, Santa Cruz, CA (US); David Joseph WETZEL, Santa Clara, CA (US); Lin XU, Fremont, CA (US)

(21) Appl. No.: 19/128,362

(22) PCT Filed: Nov. 29, 2023
(86) PCT No.: PCT/US2023/081640

§ 371 Date: May 8, 2025

Related U.S. Application Data
(60) Provisional application No. 63/430,747, filed on Dec. 7, 2022.

(51) Int. Cl. H01J 37/32; C23C 16/30; C23C 16/455; C23C 16/56

(52) U.S. Cl. CPC H01J 37/32495; C23C 16/30; C23C 16/45525; C23C 16/56

(57) ABSTRACT

A component for use in a semiconductor processing chamber is provided. A process exposed coating is on a surface of a component body, wherein the process exposed coating comprises at least one of YF3, MgF2, CeF4, HfF4, and LaF3, and wherein the process exposed coating has a thickness in a range of 10 nm to 290 nm.

### CROSS-REFERENCE TO RELATED APPLICATION

This application claims the benefit of priority of U.S. Application No. 63/430,747, filed Dec. 7, 2022, which is incorporated herein by reference for all purposes.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

The present disclosure relates to the manufacturing of semiconductor devices. More specifically, the disclosure relates to semiconductor processing chambers that may be used for thermal processes.

During semiconductor wafer processing, semiconductor processing chambers are used to process semiconductor devices. Some semiconductor processes may use thermal processes instead of plasma processes. Some thermal processes may use thermally generated radicals comprising fluorine.

### SUMMARY

To achieve the foregoing and in accordance with the purpose of the present disclosure, a component for use in a semiconductor processing chamber is provided. A process exposed coating is on a surface of a component body, wherein the process exposed coating comprises at least one of YF₃, MgF₂, CeF₄, HfF₄, and LaF₃, and wherein the process exposed coating has a thickness in a range of 10 nm to 290 nm.

In another manifestation, a method for making a component for use in a plasma processing chamber is provided. At least one of atomic layer deposition and chemical vapor deposition of a process exposed coating is deposited on a surface of a component body, wherein the process exposed coating comprises at least one of YF₃, MgF₂, CeF₄, HfF₄, and LaF₃, and wherein the process exposed coating has a thickness in a range of 10 nm to 290 nm.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart used in some embodiments.

FIGS. 2A-D are schematic views of a component body processed according to an embodiment.

FIG. 3 is a schematic view of a plasma processing system that may be used in some embodiments.

In the drawings, like reference numerals are sometimes used to designate like structural elements. It should also be appreciated that the depictions in the figures are diagrammatic and not to scale.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

During a thermal atomic layer etch, fluorine radicals are thermally generated and used for atomic layer etching. The fluorine radicals may be absorbed by various semiconductor processing chamber components, so that the semiconductor chamber components become fluorine radical sinks. When semiconductor chamber components act as fluorine radical sinks, more fluorine radicals are needed, increasing costs, and the fluorine radical distribution becomes less uniform, causing more process nonuniformities and increasing defects. In addition, fluorine radicals may erode semiconductor processing chamber components.

Some embodiments provide components of a semiconductor processing chamber that act as reduced fluorine radical sinks. Some embodiments provide components of a semiconductor processing chamber that are subjected to reduced fluorine radical erosion.

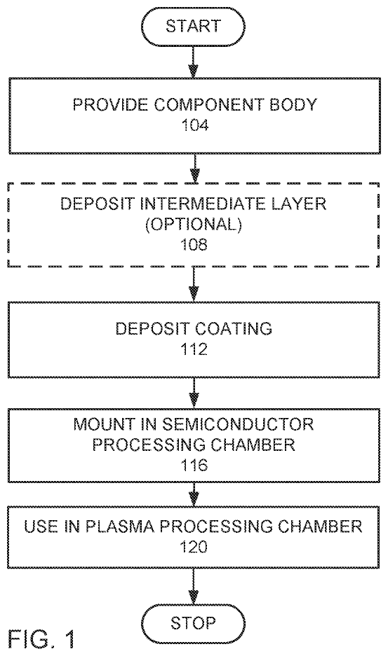

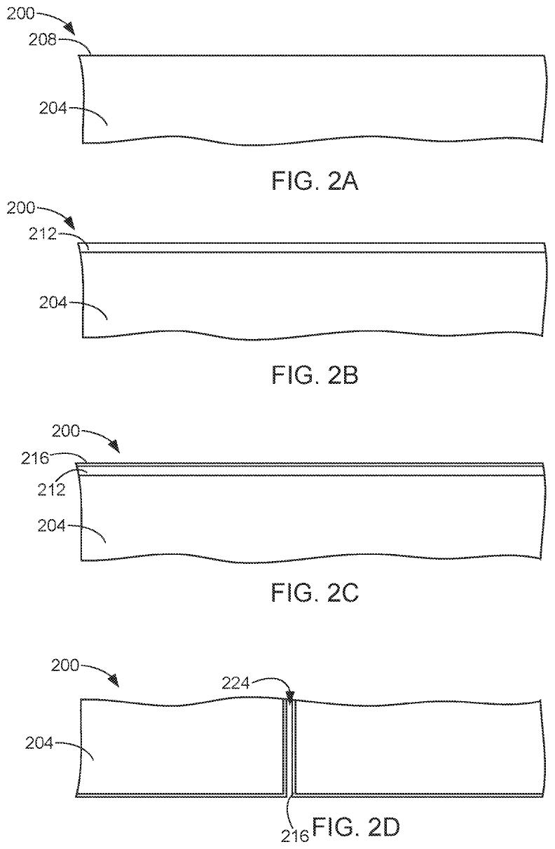

To facilitate understanding, FIG. 1 is a flow chart of process used in some embodiments that provide a component for a semiconductor processing chamber. In some embodiments, a component body is provided (step 104). FIG. 2A is a schematic cross-sectional view of part of a component body 204 of a component 200. The component body 204 has a surface 208. In some embodiments, the component body 204 comprises at least one of a metal material and ceramic material. In some embodiments, the metal material comprises at least one of aluminum, iron, titanium, nickel, and molybdenum. In some embodiments, the component body 204 comprises multiple layers of different materials, such as different metals. In some embodiments, when the metal material is iron, the component body 204 comprises stainless steel. In some embodiments, the ceramic material comprises at least one of aluminum oxide, yttria, lanthanum zirconium oxide (LZO), yttria-stabilized zirconia (YSZ), zirconia toughened alumina (ZTA), zirconia, and machinable silicate and aluminate glasses, such as MACOR® by Corning.

Optionally, in some embodiments, an intermediate layer is deposited on a surface of the 208 of the component body 204 (step 108). FIG. 2B is a schematic cross-sectional view of part of the component 200 after an intermediate layer 212 is deposited on a surface 208 of the component body 204. In some embodiments, the intermediate layer comprises a ceramic. In some embodiments, the intermediate layer is an adhesion layer. In some embodiments, oxides of the substrate are used, but aluminum oxide (Al₂O₃) is used in some embodiments because of the availability of Al₂O₃. In some embodiments, the intermediate layer 212 comprising glass or metal matrix composites (MMC) is selected in order to provide stress relief. In some embodiments, the intermediate layer comprises MMC, such as AlSiC, or a matrix of Al₂O₃ and aluminum (Al). In some embodiments, the intermediate layer 212 has a thickness in the range of 0.5 nm to 1 micron (μm). In some embodiments, the intermediate layer 212 is deposited by at least one of atomic layer deposition, chemical vapor deposition, cold spraying, glazing, hybrid aerosol deposition, detonation spraying, and physical vapor deposition. In applications, where the component has a surface to be coated that has a complex three dimensional shape, such as a showerhead or gas dispersion plate, where the inside of gas holes are to be coated, only conformal deposition processes are used. In some embodiments, the intermediate layer 212 is deposited by conformal deposition processes of at least one of atomic layer deposition or chemical vapor deposition.

A coating is deposited on a surface of the component body (step 112). In some embodiments, the deposition deposits a metal or metalloid fluoride coating, wherein the metal or metalloid is at least one of yttrium, magnesium, cerium, hafnium, and lanthanum. In some embodiments, the metal or metalloid fluoride coating is deposited by at least one of atomic layer deposition (ALD) or chemical vapor deposition (CVD). In some embodiments, the metal or metalloid fluoride coating is deposited directly on a surface of the component body. In some embodiments, the metal or metalloid fluoride coating is deposited on an intermediate layer on a surface of the component body. In some embodiments, the metal or metalloid fluoride coating comprises at least one of yttrium trifluoride (YF₃), magnesium fluoride (MgF₂), cerium (IV) fluoride (CeF₄), hafnium fluoride (HfF₄), and lanthanum trifluoride (LaF₃). In some embodiments, the metal or metalloid fluoride coating comprises at least one of yttrium trifluoride (YF₃), cerium (IV) fluoride (CeF₄), hafnium fluoride (HfF₄), and lanthanum trifluoride (LaF₃). FIG. 2C is a schematic cross-sectional view of part of the component 200 after the metal or metalloid fluoride coating 216 is deposited over the intermediate layer 212 on a surface 208 of the component body 204. In some embodiments, a YF₃ coating is deposited by an atomic layer process. In some embodiments, the metal or metalloid fluoride coating has a thickness in a range of 10 nm to 290 nm. In some embodiments, the metal or metalloid fluoride coating has a thickness in the range of 10 nm to 150 nm. In some embodiments, the metal or metalloid fluoride coating has a thickness in the range of 10 nm to 100 nm. In various embodiments, the metal or metalloid fluoride coating 216 is crystalline, amorphous, or a combination thereof. Crystalline material may be monocrystalline or polycrystalline.

FIG. 2D. is a schematic cross-sectional view of a part of a component 200 provided in some embodiments. In some embodiments, the component 200 is part of a showerhead with a passage 224, that is used as a gas passage. The gas passage may have a high aspect ratio with a depth to width aspect ratio of at least 5:1. Since the metal or metalloid fluoride coating 216 is deposited using ALD or CVD the metal or metalloid fluoride coating 216 can be deposited on non-conformal surfaces, where some of the surfaces are not along a line of sight. In addition, in some embodiments, the ALD or CVD process provides a metal or metalloid fluoride coating 216 that has a purity of at least 99% by weight with a porosity of less than 0.1% by volume. In some embodiments, the metal or metalloid fluoride coating 216 is at least 99.9% pure by weight, so that the metal or metalloid fluoride coating 216 consists essentially of one or more of YF₃, MgF₂, CeF₄, HfF₄, and LaF₃.

The component 200 is mounted in a semiconductor processing chamber (step 116). The component 200 is used in the semiconductor processing chamber to process a plurality of wafers (step 120). In some embodiments, the semiconductor process is a thermal etch process, such as a thermal atomic layer etch. In some embodiments, a first stack has a layer that is etched using a thermal atomic layer etch. In some embodiments, the first stack is removed, and a second stack is placed in the semiconductor processing chamber where a layer is etched using a thermal atomic layer etch. In some embodiments, fluorine radicals are provided during the thermal atomic layer etch. In some embodiments, the metal or metalloid fluoride coating 216 does not absorb the fluorine radicals, so that the metal or metalloid fluoride coating 216 does not act as a sink for the fluorine radicals, providing a more uniform etch of the layer on the substrate. In some embodiments, the more uniform etch provides uniformity at different locations on a wafer and also uniformity between wafers. In some embodiments, the metal or metalloid fluoride coating 216 reduces the time and number of cycles needed for component conditioning or seasoning, since some of the conditioning or seasoning may be the fluorination of surfaces of the component. A decrease in time for conditioning or seasoning allows for more wafers to be processed by the chamber over the lifetime of the component and the chamber. In addition, the metal or metalloid fluoride coating 216 reduces erosion by the fluorine radicals reducing chamber erosion and resulting contaminants. In some embodiments, the semiconductor processing exposes the metal or metalloid fluoride coating 216 to halogen gases without radicals. In order for the metal or metalloid fluoride coating 216 to prevent the component 200 from being a sink for fluorine radicals, in some embodiments, the metal or metalloid fluoride coating 216 is a process exposed or top coating with no other coating being between the metal or metalloid fluoride coating 216 and the semiconductor manufacturing process using fluorine radicals.

In some embodiments, the intermediate layer 212 is at least one of a bonding layer, a sealing layer, and a stress relief layer. A bond layer increases adhesion between the surface 208 of the component body 204 and the metal or metalloid fluoride coating 216. A sealing layer seals the surface 208 of the component body 204. A stress relief layer absorbs stress created by at least one of the component body 204 or metal or metalloid fluoride coating 216. In some embodiments, the metal or metalloid fluoride coating 216 removes the need to provide a chamber cleaning process between wafers.

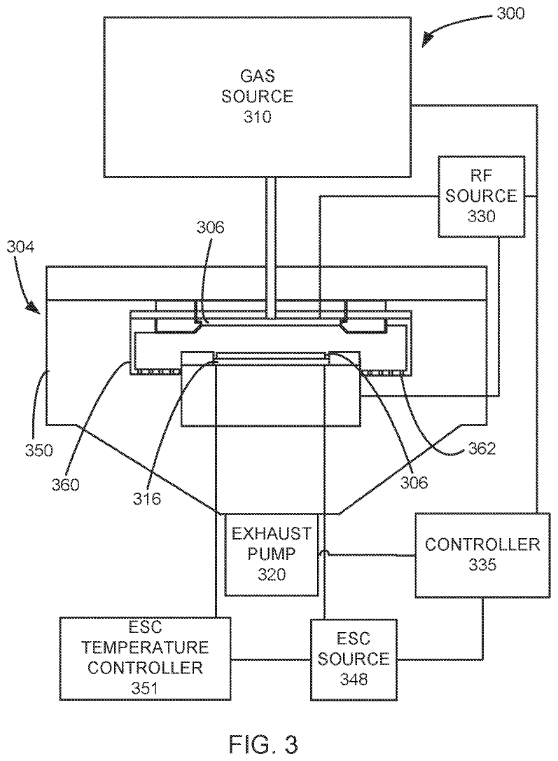

FIG. 3 is a schematic view of a semiconductor processing chamber 300 for processing substrates, in some embodiments. In some embodiments, the semiconductor processing chamber 300 comprises a gas distribution plate 306 providing a gas inlet and an electrostatic chuck (ESC) 316, within a semiconductor processing chamber 304, enclosed by a chamber wall 350. Within the semiconductor processing chamber 304, a stack 307 is positioned on top of the ESC 316. The ESC 316 may provide a bias from an ESC power source 348. A gas source 310 is connected to the semiconductor processing chamber 304 through the gas distribution plate 306. An ESC temperature controller 351 is connected to the ESC 316 and provides temperature control of the ESC 316. A radio frequency (RF) power source 330 provides RF power to the ESC 316 and an upper electrode. In some embodiments, the upper electrode is the gas distribution plate 306. In some embodiments, 400 kilohertz. (kHz), 13.56 megahertz. (MHz), 1 MHz, 2 MHz, 60 MHz, and/or optionally, 27 MHz power sources make up the RF power source 330 and the ESC power source 348. A controller 335 is controllably connected to the RF power source 330, the ESC power source 348, an exhaust pump 320, and the gas source 310. A high flow liner 360 is a liner within the semiconductor processing chamber 304, which confines gas from the gas source and has slots 362. The slots 362 maintain a controlled flow of gas to pass from the gas source 310 to the exhaust pump 320. An example of such a semiconductor processing chamber is the Flex® etch system manufactured by Lam Research Corporation of Fremont, CA. The process chamber can be a CCP (capacitively coupled plasma) reactor or an ICP (inductively coupled plasma) reactor.

In various embodiments, the component may be various parts of a plasma processing chamber, such as confinement rings, edge rings, the electrostatic chuck, ground rings, chamber liners such as a pinnacle, door liners, showerheads, or other components. Other components of other types of plasma processing chambers may be used. For example, plasma exclusion rings on a bevel etch chamber may be coated in some embodiments. In another example, the plasma processing chamber may be an inductive plasma processing chamber where the component is a dielectric inductive power window. In some embodiments one or more, but not all surfaces are coated.

While this disclosure has been described in terms of several preferred embodiments, there are alterations, permutations, modifications, and various substitute equivalents, which fall within the scope of this disclosure. It should also be noted that there are many alternative ways of implementing the methods and apparatuses of the present disclosure. It is therefore intended that the following appended claims be interpreted as including all such alterations, permutations, and various substitute equivalents as fall within the true spirit and scope of the present disclosure. As used herein, the phrase “A, B, or C” should be construed to mean a logical (“A OR B OR C”), using a non-exclusive logical “OR,” and should not be construed to mean ‘only one of A or B or C. Each step within a process may be an optional step and is not required. Different embodiments may have one or more steps removed or may provide steps in a different order. In addition, various embodiments may provide different steps simultaneously instead of sequentially.

What is claimed is:

1. A component for use in a semiconductor processing chamber, comprising:
a component body; and
a process exposed coating on a surface of the component body, wherein the process exposed coating comprises at least one of YF₃, MgF₂, CeF₄, HfF₄, and LaF₃, and wherein the process exposed coating has a thickness in a range of 10 nm to 290 nm.

2. The component, as recited in claim 1, wherein the process exposed coating has a purity of at least 99% by weight.

3. The component, as recited in claim 1, wherein the process exposed coating has a porosity of less than 0.1% by volume.

4. The component, as recited in claim 1, wherein the component body comprises at least one of a metal material and ceramic material.

5. The component, as recited in claim 1, wherein the process exposed coating has a thickness in a range of 10 nm to 100 nm.

6. The component, as recited in claim 1, further comprising an intermediate layer between the component body and the process exposed coating.

7. The component, as recited in claim 6, wherein the intermediate layer is at least one of a bonding layer, sealing layer, and a stress relief layer.

8. The component, as recited in claim 1, wherein the process exposed coating is exposed to a thermal etch process.

9. The component, as recited in claim 1, wherein the process exposed coating is crystalline.

10. The component, as recited in claim 1, wherein the process exposed coating is amorphous.

11. A method for making a component for use in a plasma processing chamber, comprising:
providing a component body; and
depositing by at least one of atomic layer deposition and chemical vapor deposition a process exposed coating on a surface of the component body, wherein the process exposed coating comprises at least one of YF₃, MgF₂, CeF₄, HfF₄, and LaF₃, and wherein the process exposed coating has a thickness in a range of 10 nm to 290 nm.

12. The method, as recited in claim 11, wherein the component body comprises at least one of a metal material and ceramic material.

13. The method, as recited in claim 11, wherein the process exposed coating has a thickness in a range of 10 nm to 100 nm.

14. The method, as recited in claim 11, further comprising depositing an intermediate layer on a surface of the component body before the depositing by at least one of atomic layer deposition and chemical vapor deposition of the process exposed coating.

15. The method, as recited in claim 14, wherein the intermediate layer is at least one of a bonding layer and a stress relief layer.

16. The method, as recited in claim 11, further comprising mounting the component in a semiconductor processing chamber.

17. The method, as recited in claim 16, further comprising exposing the process exposed coating to a thermal etch process.

18. The method, as recited in claim 11, wherein the depositing by at least one of atomic layer deposition and chemical vapor deposition uses atomic layer deposition.
